(19) United States
(12) Patent Application Publication
(10) Pub. No.: US 2009/0170244 A1
(43) Pub. Date: Jul. 2, 2009

(54) METHOD FOR MANUFACTURING A FLIP CHIP PACKAGE

(75) Inventor: Chia-Chieh Hu, Kaohsiung (TW)

Correspondence Address: VOLENTINE & WHITT PLLC, ONE FREEDOM SQUARE, 11951 FREEDOM DRIVE SUITE 1260, RESTON, VA, 20190, US

(73) Assignee: Advanced Semiconductor Engineering, Inc., Kaohsiung (TW)

(21) Appl. No.: 12/242,961

(22) Filed: Oct. 1, 2008

(30) Foreign Application Priority Data
Dec. 26, 2007 (TW) 096150370

(51) Int. Cl. H01L 21/00

(52) U.S. Cl. 438/108; 257/E21.499

(57) ABSTRACT

A method for manufacturing a flip chip package uses a dipping method to cohere liquid-state stannum onto a plurality of gold bumps of a chip. The gold bumps are correspondingly connected to a plurality of first pads of a substrate so as to connect the chip and the substrate. Finally, a protecting gel layer is disposed between the substrate and the chip, and covers the gold bumps. By utilizing the manufacturing method of the invention, the production cost can be reduced, and the manufacturing method of the invention can apply to processes in which the bump pitch is less than 60 microns. In addition, through the manufacturing method of the invention, the gold bumps are strongly joined with the first pads. Moreover, the manufacturing method of the invention can apply to various processes, so the application has a wide range of uses.

### BACKGROUND OF THE INVENTION

1. Field of the Invention

The present invention relates to a method for manufacturing a package, and more particularly to a method for manufacturing a flip chip package.

2. Description of the Related Art

In the prior art, a package with a low pin count and in need of being microminiaturized or thinned is generally manufactured by flip chip packaging. However, in a conventional flip chip packaging method, solder bumps for electrically connecting the substrate and the chip cost a lot, so gold bumps are an optimal choice to reduce the cost of the flip chip packaging. Moreover, in the conventional flip chip packaging method, the bonding of the bumps may be limited or have difficulties when the bump pitch is smaller than 60 microns.

In the prior art, gold bumps are generally bonded in the following processes: stud bump bonding (SBB), eutectic solder bonding (ESC), non-conductive film (NCF)/non-conductive paste (NCP), anisotropic conductive film (ACF)/anisotropic conductive paste (ACP), and ultrasonic gold to gold interconnect (GGI). In addition, the SBB and ESC processes are the most frequently adopted.

In the SBB process, the gold bumps must be cohered with a conductive silver paste so as to connect the substrate and the chip. However, due to its weak joining strength, the SBB process is only applicable to ceramic substrates or substrates with a low coefficient of thermal expansion (CTE). In the ESC process, the substrate is joined with the chip through direct thermal bonding method. However, solder preforms (for example, solder paste) must be disposed on the pads of the substrate in advance, and the current technique is only applicable to processes with a bump pitch larger than 60 microns. Moreover, as the price of the substrate is high, the production cost is increased. In addition, the solder preforms are generally a layer of solder paste, and are very heavy, so it is not easy to dispose the solder preforms on the gold bumps by dipping.

In view of the above, the conventional flip chip packaging method has many defects, such as the weak joining strength of the bumps, its incapability of being applied to processes with a bump pitch smaller than 60 microns, and a high production cost.

Therefore, there is a need for a method for manufacturing a flip chip package to solve the above problem.

### SUMMARY OF THE INVENTION

The present invention is directed to a method for manufacturing a flip chip package. The method includes: (a) providing a substrate having a first surface with a plurality of first pads disposed thereon; (b) providing a chip is having a plurality of gold bumps corresponding to the first pads; (c) cohering a liquid-state stannum onto each of the gold bumps; (d) connecting the corresponding first pads and gold bumps; and (e) forming a protecting gel layer between the substrate and the chip that at least covers the gold bumps.

In the method for manufacturing a flip chip package provided by the present invention, the liquid-state stannum is cohered onto each of the gold bumps by dipping. As a result, the gold bumps can be directly connected to the pads plated with a nickel-gold layer on the substrate, instead of through solder performs disposed on the first pads of the substrate in advance. When the method is applied to a wafer-level package (WLP), the manufacturing process stays the same, and thus, the production cost is reduced. Further, as the liquid-state stannum is cohered onto each of the gold bumps by dipping, the manufacturing method of the present invention is applicable to processes with a bump pitch smaller than 60 microns, and the gold bumps are strongly joined with the first pads. In addition, the manufacturing method of the present invention can be applied to various processes, so the application has a wide range of uses.

### BRIEF DESCRIPTION OF THE DRAWINGS

FIG. 1 is a flow chart of a method for manufacturing a flip chip package according to the present invention;

FIG. 2 is a schematic view of a substrate according to the present invention;

FIGS. 3A to 4 are schematic views illustrating the bonding of the substrate with a chip according to the present invention;

FIGS. 3B and 3C are schematic views of two types of gold bumps according to the present invention;

FIG. 3D is a schematic view illustrating the cohesion of a soldering flux onto each of the gold bumps according to the present invention;

FIG. 3E is a schematic view illustrating the cohesion of a liquid-state stannum onto each of the gold bumps according to the present invention; and

FIG. 5 is a schematic view of a flip chip package according to the present invention.

### DETAILED DESCRIPTION OF THE INVENTION

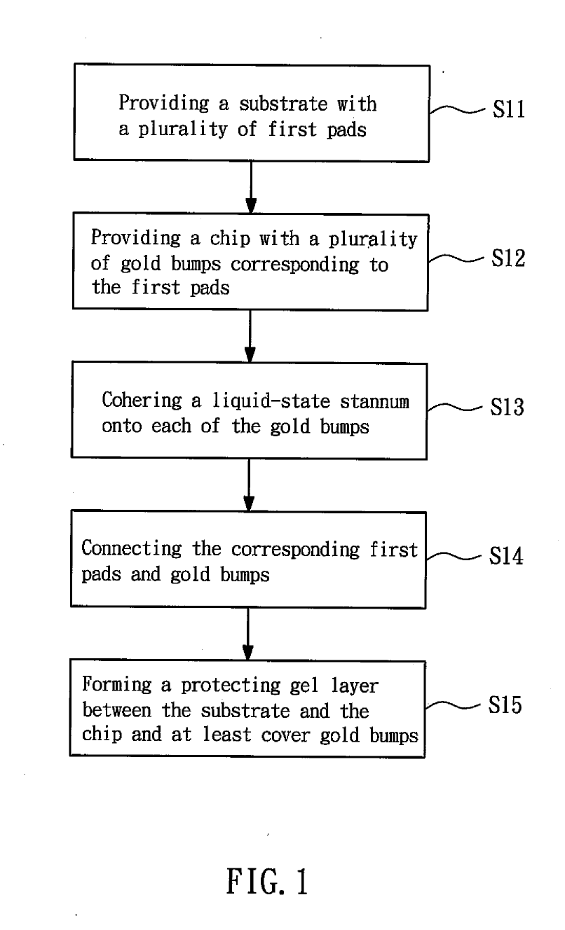

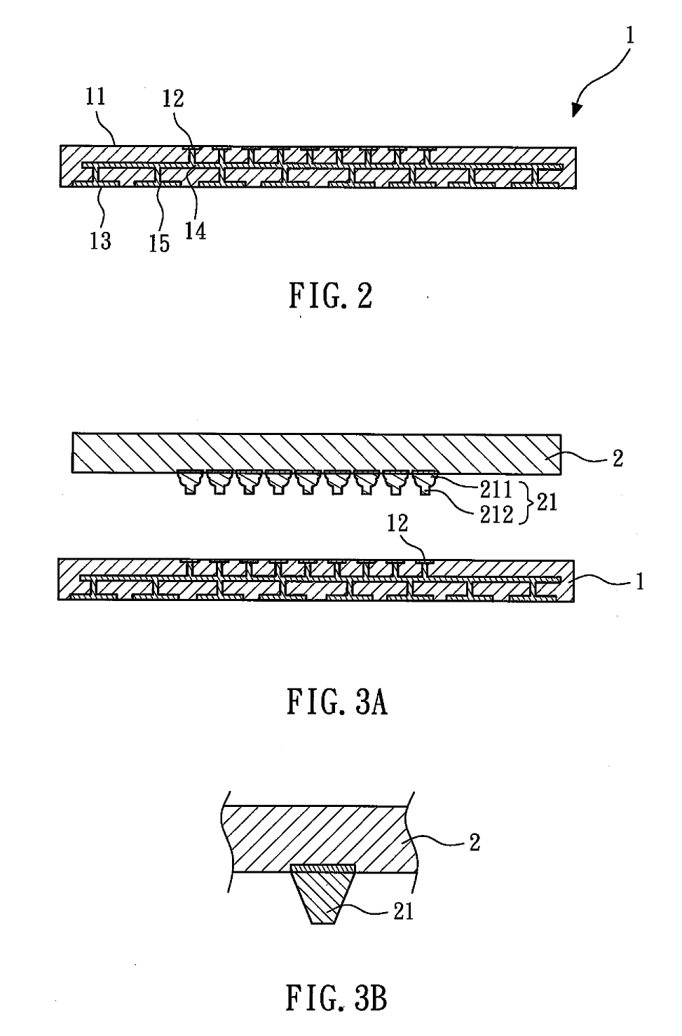

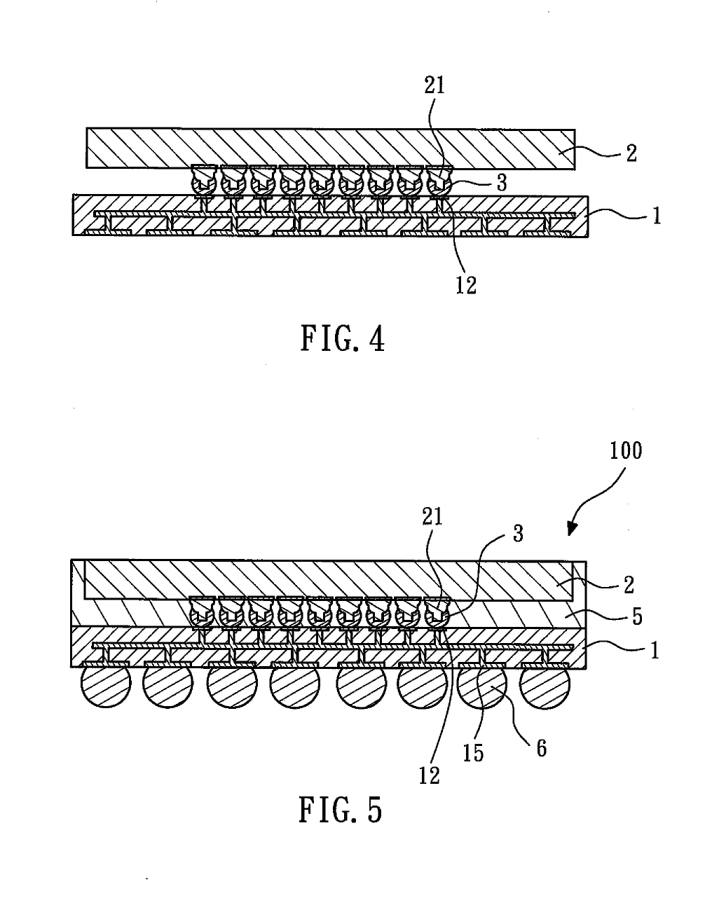

FIG. 1 is a flow chart of a method for manufacturing a flip chip package according to the present invention. FIGS. 2 to 5 are schematic views illustrating the method for manufacturing a flip chip package according to the present invention. The method for manufacturing a flip chip package provided by the present invention can be used as a substitute for the conventional SBB, ESC, NCF/NCP, ACF/ACP, or ultrasonic GGI process.

Referring to FIGS. 1 and 2 to 5, in Step S11 and FIG. 2, first, a substrate 1 is provided. The substrate 1 has a first surface 11 with a plurality of first pads 12 disposed thereon. In this embodiment, the substrate 1 further includes a second surface 13, a plurality of circuits 14, and a plurality of second pads 15. The second surface 13 is opposite the first surface 11. The second pads 15 are disposed on the second surface 13, and the circuits 14 electrically connect the second pads 15 and the first pads 12.

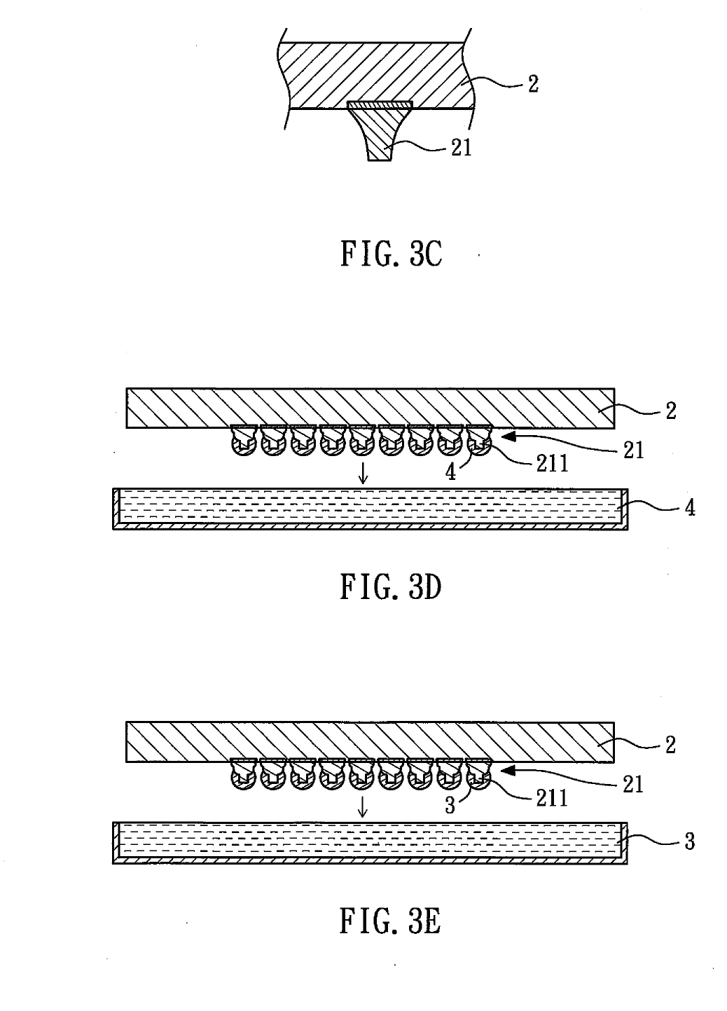

Referring to Step S12 and FIG. 3A, a chip 2 is provided. The chip 2 has a plurality of gold bumps 21 corresponding to the first pads 12. In this embodiment, each of the gold bumps 21 has a base portion 211 and an upper portion 212, and the base portion 211 has a width larger than that of the upper portion 212. The thickness of the upper portion 212 is preferably two-thirds of the total thickness of the gold bump 21.

In this embodiment, the upper portion 212 and the base portion 211 form a step-like configuration, and in another application, the upper portion 212 and the base portion 211 form a trapezoid configuration (as shown in FIG. 3B). Alternatively, the gold bump 21 narrows from the base portion 211 to the upper portion 212, so radial sides of the gold bump 21 assumes a parabolic curve (as shown in FIG. 3C).

Referring to Step S13, a liquid-state stannum 3 is cohered onto each of the gold bumps 21. In this embodiment, Step S13 further includes: cohering a soldering flux 4 onto each of the gold bumps 21 and covering at least a part of the upper portion 212 (as shown in FIG. 3D); and cohering the liquid-state stannum 3 onto the gold bump 21 and covering at least a part of the upper portion 212, and removing the soldering flux 4 (as shown in FIG. 3E). The soldering flux 4 and the liquid-state stannum 3 are cohered onto the gold bumps 21 by dipping, so as to control the cohesion height. Moreover, as the width of the base portion 211 is larger than that of the upper portion 212, and the thickness of the upper portion 212 is two-thirds of the total thickness of the gold bump 21, the soldering flux 4 and the liquid-state stannum 3 are only cohered on the upper portions 212 of the gold bumps 21. Therefore, the gold bumps 21 may not be electrically connected due to the lateral spreading of the liquid-state stannum 3 when the liquid-state stannum 3 is extruded during the flip chip bonding, and thus, the size of the flip chip package can be further reduced.

The soldering flux 4 is cohered onto the gold bumps 21 at a first temperature. In this embodiment, the first temperature is 25° C. The liquid-state stannum 3 is cohered onto the gold bumps 21 at a second temperature, and the soldering flux 4 is removed by volatilization at the second temperature. In this embodiment, a working platform (not shown) containing a solder is provided. Then, the solder is continuously heated to the second temperature (230° C.) so that it becomes the liquid-state stannum 3. Afterward, the liquid-state stannum 3 is cohered onto the gold bumps 21.

Referring to Step S14, the corresponding first pads 12 and gold bumps 21 are connected, preferably through thermal bonding method.

Referring to Step S15, a protecting gel layer 5 is formed between the substrate 1 and the chip 2 and at least covers the gold bumps 21, thus completing the flip chip package 100 of the present invention. The protecting gel layer 5 may be a molding compound or underfill. Further, after the protecting gel layer 5 is formed, the method further includes a step of configuring solder balls to dispose solder balls 6 on each of the second pads 15. As a result, the flip chip package 100 can be electrically connected to an external component or device (not shown).

In the method for manufacturing a flip chip package provided by the present invention, the liquid-state stannum is cohered onto each of the gold bumps by dipping. Thus, the gold bumps can be directly connected to the pads plated with a nickel-gold layer on the substrate, instead of through solder performs disposed on the first pads of the substrate in advance. Therefore, when the method is applied to a WLP, for example, a mixed WLP (flip chip and bonding package), the manufacturing process stays the same, and thus, the production cost is reduced. Further, as the liquid-state stannum is cohered onto each of the gold bumps by dipping, the manufacturing method of the present invention is applicable to processes with a bump pitch smaller than 60 microns, and the gold bumps are strongly joined with the first pads. In addition, the manufacturing method of the present invention can be applied to various processes so the application has a wide range of uses.

While the embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications that maintain the spirit and scope of the present invention are within the scope as defined in the appended claims.

What is claimed is:

1. A method for manufacturing a flip chip package, comprising:
(a) providing a substrate that has a first surface with a plurality of first pads disposed thereon;
(b) providing a chip that has a plurality of gold bumps corresponding to the first pads;
(c) cohering a liquid-state stannum onto each of the gold bumps;
(d) connecting the corresponding first pads and the gold bumps;
(e) forming a protecting gel layer between the substrate and the chip and at least covering the gold bumps.

2. The method according to claim 1, wherein in Step (b), each of the gold bumps has a base portion and an upper portion, and the base portion has a width larger than that of the upper portion.

3. The method according to claim 2, wherein the thickness of the upper portion is two-thirds of the total thickness of the gold bump.

4. The method according to claim 2, wherein in Step (b), the upper portion and the base portion form a step-like configuration.

5. The method according to claim 2, wherein in Step (b), the upper portion and the base portion form a trapezoid configuration.

6. The method according to claim 2, wherein in Step (b), the gold bump narrows from the base portion to the upper portion, so radial sides of the gold bump assume a parabolic curve.

7. The method according to claim 2, wherein Step (c) comprises:
(c1) cohering a soldering flux onto each of the gold bumps and covering at least a part of the upper portion; and
(c2) cohering the liquid-state stannum onto the gold bump and covering at least a part of the upper portion, and removing the soldering flux.

8. The method according to claim 7, wherein in Steps (c1) and (c2), the soldering flux and the liquid-state stannum are cohered onto the gold bumps by dipping, so as to control the cohesion height.

9. The method according to claim 7, wherein in Step (c1), the soldering flux is cohered onto the gold bump at a first temperature.

10. The method according to claim 9, wherein the first temperature is 25° C.

11. The method according to claim 7, wherein in Step (c2), the liquid-state stannum is cohered onto the gold bump at a second temperature, and the soldering flux is removed by volatilization at the second temperature.

12. The method according to claim 11, wherein the second temperature is 230° C.

13. The method according to claim 1, wherein in Step (d), the corresponding first pads and gold bumps are bonded through thermal bonding method.

14. The method according to claim 1, wherein the substrate further comprises a second surface opposite the first surface, and the second surface has a plurality of second pads electrically connected to the first pads.

15. The method according to claim 14, after Step (e), further comprising a step of configuring solder balls to dispose solder balls on each of the second pads.
